(19) United States
(12) Patent Application Publication
(10) Pub. No.: US 2026/0235675 A1
(43) Pub. Date: Aug. 13, 2026

(54) SEMICONDUCTOR DEVICE AND METHOD OF INSPECTING SEMICONDUCTOR DEVICE

(71) Applicant: CANON KABUSHIKI KAISHA, Tokyo (JP)

(72) Inventor: EIJI AIZAWA, Tokyo (JP)

(21) Appl. No.: 19/536,429

(22) Filed: Feb. 11, 2026

(30) Foreign Application Priority Data
Feb. 13, 2025 (JP) 2025-021191

(51) Int. Cl. G01R 31/3185; G06F 11/22

(52) U.S. Cl. CPC G01R 31/318536; G01R 31/318547; G01R 31/318569; G06F 11/2215

(57) ABSTRACT

One aspect of the present disclosure relates to a method of inspecting a semiconductor device including a plurality of processors each of which has a scan chain. The method comprises: first determining including: inputting scan signals to the plurality of processors; and determining whether a failure occurs in any of the plurality of processors based on output signals of the plurality of processors and an expectation value corresponding to the scan signals; and second determining including: inputting the scan signal to a part of the plurality of processors in a case where the first determining determines that the failure occurs; and determining whether the failure occurs in the part of the plurality of processors based on the expectation value and an output signal of the part of the plurality of processors.

### BACKGROUND

### Field of the Technology

The present disclosure relates to a semiconductor device and a method of inspecting a semiconductor device.

### Description of the Related Art

Japanese Patent Laid-Open No. 2010-041705 discloses that, if a basic cell has a failure, a redundant cell is used instead of the basic cell to avoid malfunction of a semiconductor device.

However, according to the technique disclosed in Japanese Patent Laid-Open No. 2010-041705, it is not easy to identify the cell having a failure, which takes a large amount of time and cost for device inspection.

### SUMMARY

The present disclosure is directed to providing a method for easily identifying a processor having a failure in inspection of semiconductor devices.

According to an aspect of the present disclosure, there is provided a method of inspecting a semiconductor device including a plurality of processors each of which has a scan chain, the method comprising: first determining including: inputting scan signals to the plurality of processors; and determining whether a failure occurs in any of the plurality of processors based on output signals of the plurality of processors and an expectation value corresponding to the scan signals; and second determining including: inputting the scan signal to a part of the plurality of processors in a case where the first determining determines that the failure occurs; and determining whether the failure occurs in the part of the plurality of processors based on the expectation value and an output signal of the part of the plurality of processors.

According to another aspect of the present disclosure, there is provided a semiconductor device comprising: a plurality of processors each of which has a scan chain; a redundant processor to be replaced with the processor having a failure, the redundant processor having a configuration corresponding to the processor; a scan expander that expands an input signal to a plurality of scan signals; a scan compressor that receives a plurality of output signals corresponding to the plurality of scan signals from the plurality of processors and the redundant processor, and output the plurality of output signals as a single signal; a plurality of input signal paths that transmits the plurality of scan signals from the scan expander to the plurality of processors and the redundant processor; a plurality of output signal paths that transmits the plurality of output signals from the plurality of processors and the redundant processor to the scan compressor; and a plurality of bypasses used to transmit the plurality of scan signals from the scan expander to the scan compressor by detouring around the plurality of processors.

Features of the present disclosure will become apparent from the following description of embodiments with reference to the attached drawings. The following description of embodiments is described by way of example.

### BRIEF DESCRIPTION OF THE DRAWINGS

FIG. 1 is a block diagram showing a schematic configuration of the semiconductor device according to a first embodiment.

FIG. 2 is a block diagram showing another schematic configuration of the semiconductor device according to the first embodiment.

FIG. 3 is a flow chart showing the steps of identifying a processor having a failure in the semiconductor device, and replacing the processor with a redundant processor according to the first embodiment.

FIG. 4 is a flow chart showing the steps of identifying a processor having a failure in the semiconductor device, and replacing the processor with a redundant processor according to a second embodiment.

FIG. 5 is a block diagram showing a schematic configuration of equipment according to a third embodiment.

FIGS. 6A and 6B are block diagrams showing schematic configurations of equipment according to a fourth embodiment.

### DESCRIPTION OF THE EMBODIMENTS

Hereinafter, embodiments of the present disclosure will be described with reference to the drawings. The same or corresponding elements are denoted by the same reference numerals throughout the several drawings, and the description thereof may be omitted or simplified.

### First Embodiment

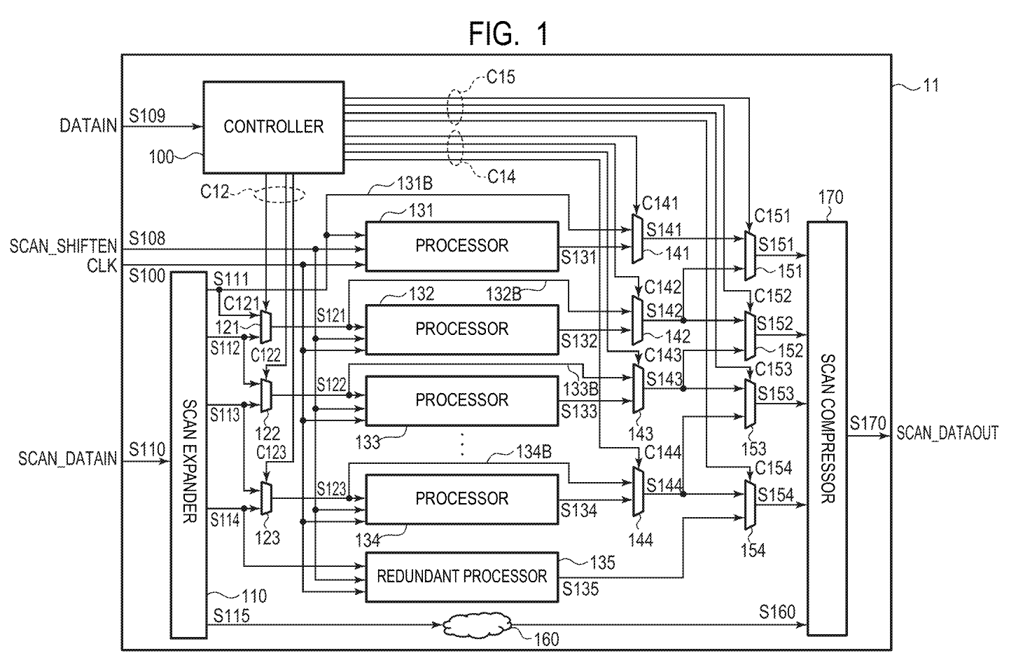

A semiconductor device according to the present disclosure will be described with reference to FIG. 1. FIG. 1 is a block diagram showing a schematic configuration of a semiconductor device 11 according to the present embodiment. The semiconductor device 11 includes a controller 100, a scan expander 110, selectors 121 to 123, processors 131 to 134, a redundant processor 135, selectors 141 to 144, selectors 151 to 154, a circuit unit 160, and a scan compressor 170.

The controller 100 controls the operations of the selectors 121 to 123, the selectors 141 to 144, and the selectors 151 to 154. Specifically, the controller 100 receives a setting signal S109 including setting parameters for a scan test. The setting signal S109 is used to generate a test pattern that is described later. In response to the setting signal S109, the controller 100 generates control signals C12, C14, and C15 for controlling the operations of the selectors 121 to 123, the selectors 141 to 144, and the selectors 151 to 154. The controller 100 is connected to the selectors 121 to 123, the selectors 141 to 144, and the selectors 151 to 154 for allowing the transmission of the control signals. The controller 100 outputs the control signal C12 to the selectors 121 to 123. In addition, the controller 100 outputs the control signal C14 to the selectors 141 to 144. Furthermore, the controller 100 outputs the control signal C15 to the selectors 151 to 154.

The scan expander 110 expands or decompresses a scan data signal used for the scan test. Specifically, the scan expander 110 receives a compressed scan data signal S110. The scan data signal S110 is output from, for example, a tester that inspects the semiconductor device 11. The scan expander 110 expands or decompresses the scan data signal S110 into pattern signals S111 to S115. The scan expander 110 is connected to the selectors 121 to 123, the processor 131, the redundant processor 135, the selector 141, and the circuit unit 160 via input signal paths and a bypass 131B for allowing transmission of pattern signals (scan signals). The scan expander 110 outputs a pattern signal S111 to the selector 121, the processor 131, and the selector 141. The scan expander 110 outputs a pattern signal S112 to the selector 121 and the selector 122. The scan expander 110 outputs a pattern signal S113 to the selector 122 and the selector 123. The scan expander 110 outputs a pattern signal S114 to the selector 123 and the redundant processor 135. The scan expander 110 outputs a pattern signal S115 to the circuit unit 160.

The selectors 121 to 123 select one signal from multiple input signals, and output the selected signal to the processors 132 to 134 via the input signal paths. Specifically, the selector 121 receives the pattern signals S111, S112 from the scan expander 110. In addition, the selector 121 receives the control signal C121 included in the control signals C12 from the controller 100. The selector 121 selects the pattern signal S111 or the pattern signal S112 in accordance with the control signal C121. The selector 121 is connected to the processor 132 and the selector 142 for allowing transmission of the pattern signal. The selector 121 outputs the selected pattern signal to the processor 132 and the selector 142 as the selection signal S121.

The selector 122 receives the pattern signals S112, S113 from the scan expander 110. In addition, the selector 122 receives a control signal C122 included in the control signal C12 from the controller 100. The selector 122 selects the pattern signal S112 or the pattern signal S113 according to the control signal C122. The selector 122 is connected to the processor 133 and the selector 143 for allowing transmission of the pattern signal. The selector 122 outputs the selected pattern signal to the processor 133 and the selector 143 as a selection signal S122.

The selector 123 receives the pattern signals S113, S114 from the scan expander 110. In addition, the selector 123 receives a control signal C123 included in the control signal C12 from the controller 100. The selector 123 selects the pattern signal S113 or the pattern signal S114 according to the control signal C123. The selector 123 is connected to the processor 134 and the selector 144 for allowing transmission of the pattern signal. The selector 123 outputs the selected pattern signal to the processor 134 and the selector 144 as a selection signal S123.

The processors 131 to 134 and the redundant processor 135 are signal processing circuits having logically equivalent configurations. That is, the semiconductor device 11 includes multiple signal processors (signal processing unit), and at least one of the signal processors is the redundant processor 135 (redundant signal processing unit). The processors 131 to 134 and the redundant processor 135 have a scan chain including multiple flip-flops. In the normal operation, the processors 131 to 134 and the redundant processor 135 perform predetermined signal processing on input data in accordance with a clock signal S100. The processors 131 to 134 and the redundant processor 135 output data after the signal processing to the selectors 141 to 144 via output signal paths. The redundant processor 135 is used as an alternative processor in a case where a failure is detected in the processors 131 to 134. That is, if a failure is detected in any of the processors 131 to 134, the redundant processor 135 is replaced with the processor having the failure. The signal processing executed by the redundant processor 135 is the same as the signal processing executed by the processors 131 to 134. The number of processors included in the semiconductor device 11 is not limited to the present embodiment, and may be, for example, N (N is a natural number of 2 or more).

Hereinafter, the operations of the processors 131 to 134 and the redundant processor 135 at the time of the scan test will be described. The processors 131 to 134 and the redundant processor 135 receive the clock signal S100, a shift enable signal S108, and the pattern signals S111 to S114. The scan test is performed on the processors 131 to 134 and the redundant processor 135 using the clock signal S100, the shift enable signal S108, and the pattern signals S111 to S114.

Specifically, the processor 131 receives the pattern signal S111 from the scan expander 110. The processor 131 stores the pattern signal S111 in the flip-flop constituting the scan chain in accordance with the clock signal S100. The processor 131 is connected to the selector 141 for allowing transmission of signals. The processor 131 outputs the pattern signal S111 read from the scan chain to the selector 141 as an output signal S131 in response to the shift enable signal S108.

The processor 132 receives the selection signal S121 from the selector 121. The selection signal S121 corresponds to the pattern signal S111 or the pattern signal S112. The processor 132 stores the selection signal S121 in the flip-flops constituting the scan chain in accordance with the clock signal S100. The processor 132 is connected to the selector 142 for allowing transmission of signals. The processor 132 outputs the selection signal S121 read from the scan chain to the selector 142 as an output signal S132 in accordance with the shift enable signal S108.

The processor 133 receives the selection signal S122 from the selector 122. The selection signal S122 corresponds to the pattern signal S112 or the pattern signal S113. The processor 133 stores the selection signal S122 in the flip-flops constituting the scan chain in accordance with the clock signal S100. The processor 133 is connected to the selector 143 for allowing transmission of signals. The processor 133 outputs the selection signal S122 read from the scan chain to the selector 143 as an output signal S133 in response to the shift enable signal S108.

The processor 134 receives the selection signal S123 from the selector 123. The selection signal S123 corresponds to the pattern signal S113 or the pattern signal S114. The processor 134 stores the selection signal S123 in the flip-flops constituting the scan chain in accordance with the clock signal S100. The processor 134 is connected to the selector 144 for allowing transmission of signals. The processor 134 outputs the selection signal S123 read from the scan chain to the selector 144 as an output signal S134 in response to the shift enable signal S108.

The redundant processor 135 receives the pattern signal S114 from the scan expander 110. The redundant processor 135 stores the pattern signal S114 in the flip-flop constituting the scan chain in accordance with the clock signal S100. The redundant processor 135 is connected to the selector 154 for allowing transmission of signals. The redundant processor 135 outputs the pattern signal S114 read from the scan chain to the selector 154 as an output signal S135 in response to the shift enable signal S108.

The number of processors included in the semiconductor device 11 is not limited to four. For example, the semiconductor device 11 may include three or less processors, or may include five or more processors.

The selectors 141 to 144 select one signal from multiple input signals, and output the selected signal to the selectors 151 to 154 via output signal paths. Specifically, the selector 141 receives the output signal S131 from the processor 131. In addition, the selector 141 receives the pattern signal S111 from the scan expander 110 via the bypass 131B. The bypass 131B is a path for sending the pattern signal S111 to the selector 141 while detouring around the processor 131. That is, the selector 141 may receive the pattern signal S111 via the bypass 131B without passing through the scan chain of the processor 131. Further, the selector 141 receives a control signal C141 included in the control signal C14 from the controller 100. The selector 141 selects the output signal S131 or the pattern signal S111 in accordance with the control signal C141. The selector 141 is connected to the selector 151 for allowing transmission of signals. The selector 141 outputs the selected signal to the selector 151 as a selection signal S141.

The selector 142 receives the output signal S132 from the processor 132. In addition, the selector 142 receives the selection signal S121 from the selector 121 via a bypass 132B. The bypass 132B is a path for detouring around the processor 132 and sending the selection signal S121 to the selector 142. That is, the selector 142 may receive the selection signal S121 via the bypass 132B without passing through the scan chain of the processor 132. Further, the selector 142 receives a control signal C142 included in the control signal C14 from the controller 100. The selector 142 selects the output signal S132 or the selection signal S121 in accordance with the control signal C142. The selector 142 is connected to the selector 152 for allowing transmission of signals. The selector 142 outputs the selected signal to the selector 152 as a selection signal S142.

The selector 143 receives the output signal S133 from the processor 133. In addition, the selector 143 receives the selection signal S122 from the selector 122 via a bypass 133B. The bypass 133B is a path for detouring around the processor 133 and sending the selection signal S122 to the selector 143. That is, the selector 143 may receive the selection signal S122 via the bypass 133B without passing through the scan chain of the processor 133. Further, the selector 143 receives a control signal C143 included in the control signal C14 from the controller 100. The selector 143 selects the output signal S133 or the selection signal S122 according to the control signal C143. The selector 143 is connected to the selector 153 for allowing transmission of signals. The selector 143 outputs the selected signal to the selector 153 as a selection signal S143.

The selector 144 receives the output signal S134 from the processor 134. In addition, the selector 144 receives the selection signal S123 from the selector 123 via a bypass 134B. The bypass 134B is a path for detouring around the processor 134 and sending the selection signal S123 to the selector 144. That is, the selector 144 may receive the selection signal S123 via the bypass 134B without passing through the scan chain of the processor 134. Further, the selector 144 receives a control signal C144 included in the control signal C14 from the controller 100. The selector 144 selects the output signal S134 or the selection signal S123 in accordance with the control signal C144. The selector 144 is connected to the selector 154 for allowing transmission of signals. The selector 144 outputs the selected signal to the selector 154 as a selection signal S144.

The selectors 151 to 154 select one signal from multiple input signals, and output the selected signal to the scan compressor 170 via output signal paths. Specifically, the selector 151 receives the selection signal S141 from the selector 141. In addition, the selector 151 receives the selection signal S142 from the selector 142. Further, the selector 151 receives a control signal C151 included in the control signal C15 from the controller 100. The selector 151 selects the selection signal S141 or the selection signal S142 in accordance with the control signal C151. The selector 151 is connected to the scan compressor 170 for allowing transmission of signals. The selector 151 outputs the selected signal to the scan compressor 170 as a selection signal S151.

The selector 152 receives the selection signal S142 from the selector 142. In addition, the selector 152 receives the selection signal S143 from the selector 143. Further, the selector 152 receives a control signal C152 included in the control signal C15 from the controller 100. The selector 152 selects the selection signal S142 or the selection signal S143 in accordance with the control signal C152. The selector 152 is connected to the scan compressor 170 for allowing transmission of signals. The selector 152 outputs the selected signal to the scan compressor 170 as a selection signal S152.

The selector 153 receives the selection signal S143 from the selector 143. In addition, the selector 153 receives the selection signal S144 from the selector 144. Further, the selector 153 receives a control signal C153 included in the control signal C15 from the controller 100. The selector 153 selects the selection signal S143 or the selection signal S144 in accordance with the control signal C153. The selector 153 is connected to the scan compressor 170 for allowing transmission of signals. The selector 153 outputs the selected signal to the scan compressor 170 as a selection signal S153.

The selector 154 receives the selection signal S144 from the selector 144. In addition, the selector 154 receives the output signal S135 from the redundant processor 135. Further, the selector 154 receives a control signal C154 included in the control signal C15 from the controller 100. The selector 154 selects the selection signal S144 or the output signal S135 in accordance with the control signal C154. The selector 154 is connected to the scan compressor 170 for allowing transmission of signals. The selector 154 outputs the selected signal to the scan compressor 170 as a selection signal S154.

The circuit unit 160 includes a combinational circuit, a sequential circuit, and the like. The circuit unit 160 performs predetermined signal processing on input data. The circuit unit 160 outputs data after the signal processing. In the scan test, the circuit unit 160 receives the pattern signal S115 from the scan expander 110. The circuit unit 160 performs predetermined signal processing on the pattern signal S115, and outputs the data after the signal processing to the scan compressor 170 as an output signal S160.

The scan compressor 170 compresses multiple signals indicating results of the scan test for the processors 131 to 134 and the redundant processor 135 according to the number of output terminals, and outputs the compressed signal from the output terminals as one signal. Specifically, the scan compressor 170 receives the selection signals S151 to S154 from the selectors 151 to 154. The scan compressor 170 receives the output signal S160 from the circuit unit 160. The scan compressor 170 compresses the selection signals S151 to S154 and the output signal S160, and outputs the compressed signal as an output signal S170. The output signal S170 is output to, for example, a tester that inspects the semiconductor device 11. In the tester, a value indicated by the output signal S170 is compared with an expected value, and it is determined whether the processors have a failure based on the result of the comparison.

### Comparative Example

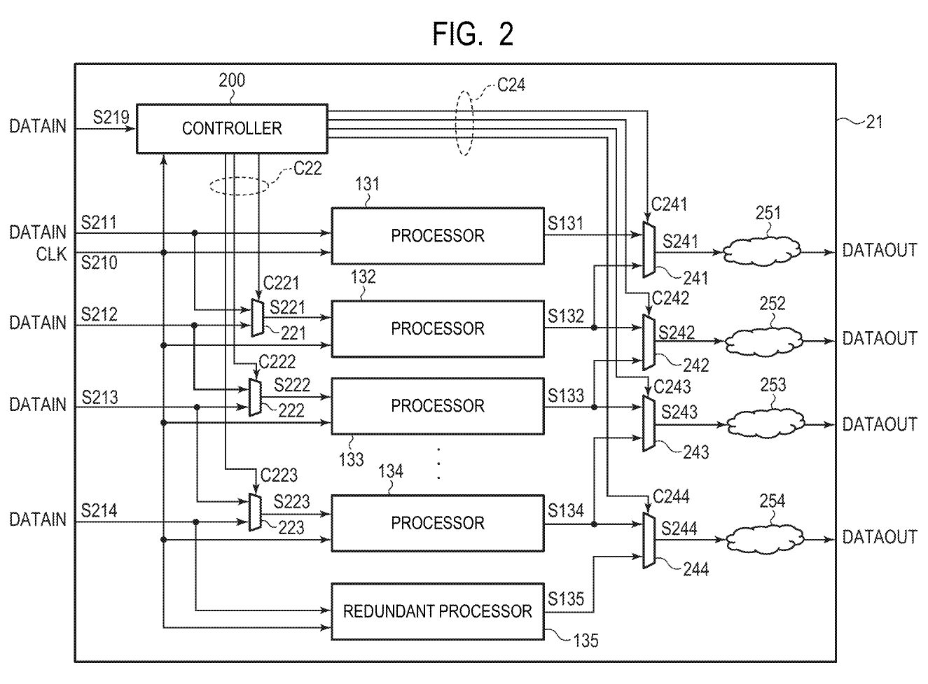

A comparative example related to the semiconductor device according to the present disclosure will be described with reference to FIG. 2. FIG. 2 is a block diagram showing a schematic configuration of a semiconductor device 21 according to a comparative example of the present disclosure. The semiconductor device 21 includes a controller 200, selectors 221 to 223, the processors 131 to 134, the redundant processor 135, selectors 241 to 244, and circuit units 251 to 254. The semiconductor device 21 differs from the semiconductor device 11 according to the present disclosure in that the semiconductor device 21 does not include the bypass 131B, 132B, 133B and 134B, the scan expander 110, and the scan compressor 170.

The controller 200 controls the operations of the selectors 221 to 223 and the selectors 241 to 244. Specifically, the controller 200 receives a setting signal S219 including setting parameters and a clock signal S210. The controller 200 generates control signals C22 and C24 for controlling the operations of the selectors 221 to 223 and the selectors 241 to 244 based on the setting signal S219 and the clock signal S210. The controller 200 is connected to the selectors 221 to 223 and the selectors 241 to 244 for allowing transmission of the control signals C22 and C24. The controller 200 outputs the control signal C22 to the selectors 221 to 223. In addition, the controller 200 outputs the control signal C24 to the selectors 241 to 244.

The selectors 221 to 223 select one signal from multiple input signals and output the selected signal to the processors 132 to 134. Specifically, the selector 221 receives a data signal S211 and a data signal S212. In addition, the selector 221 receives a control signal C221 included in the control signal C22 from the controller 200. The selector 221 selects the data signal S211 or the data signal S212 in accordance with the control signal C221. The selector 221 is connected to the processor 132 for allowing transmission of data signals. The selector 221 outputs the selected data signal to the processor 132 as a selection signal S221.

The selector 222 receives the data signal S212 and a data signal S213. In addition, the selector 222 receives a control signal C222 included in the control signal C22 from the controller 200. The selector 222 selects the data signal S212 or the data signal S213 according to the control signal C222. The selector 222 is connected to the processor 133 for allowing transmission of data signals. The selector 222 outputs the selected data signal to the processor 133 as a selection signal S222.

The selector 223 receives the data signal S213 and a data signal S214. In addition, the selector 223 receives a control signal C223 included in the control signal C22 from the controller 200. The selector 223 selects the data signal S213 or the data signal S214 according to the control signal C223. The selector 223 is connected to the processor 134 for allowing transmission of data signals. The selector 223 outputs the selected data signal to the processor 134 as a selection signal S223.

The processors 131 to 134 and the redundant processor 135 shown in FIG. 2 have the same configuration as the processors 131 to 134 and the redundant processor 135 shown in FIG. 1. The processors 131 to 134 and the redundant processor 135 perform predetermined signal processing on input data in accordance with the clock signal S210. Then, the processors 131 to 134 and the redundant processor 135 output data after the signal processing to the selectors 241 to 244.

The processor 131 receives the data signal S211. The processor 131 performs predetermined signal processing on the data signal S211 in accordance with the input clock signal S210. The processor 131 is connected to the selector 241 for allowing transmission of signals. The processor 131 outputs the data signal S211 after the signal processing to the selector 241 as an output signal S131.

The processor 132 receives the selection signal S221 from the selector 221. The selection signal S221 corresponds to the data signal S211 or the data signal S212. The processor 132 performs predetermined signal processing on the selection signal S221 in accordance with the input clock signal S210. The processor 132 is connected to the selector 241 and the selector 242 for allowing transmission of signals. The processor 132 outputs the selection signal S221 after the signal processing to the selector 241 and the selector 242 as an output signal S132.

The processor 133 receives the selection signal S222 from the selector 222. The selection signal S222 corresponds to the data signal S212 or the data signal S213. The processor 133 performs predetermined signal processing on the selection signal S222 in accordance with the input clock signal S210. The processor 133 is connected to the selector 242 and the selector 243 for allowing transmission of signals. The processor 133 outputs the selection signal S222 after the signal processing to the selector 242 and the selector 243 as an output signal S133.

The processor 134 receives the selection signal S223 from the selector 223. The selection signal S223 corresponds to the data signal S213 or the data signal S214. The processor 134 performs predetermined signal processing on the selection signal S223 in accordance with the input clock signal S210. The processor 134 is connected to the selector 243 and the selector 244 for allowing transmission of signals. The processor 134 outputs the selection signal S223 after the signal processing to the selector 243 and the selector 244 as an output signal S134.

The redundant processor 135 receives the data signal S214. The redundant processor 135 performs predetermined signal processing on the data signal S214 in accordance with the input clock signal S210. The redundant processor 135 is connected to the selector 244 for allowing transmission of signals. The redundant processor 135 outputs the data signal S214 after the signal processing to the selector 244 as an output signal S135.

The selectors 241 to 244 select one signal from multiple input signals and output the selected signal to the circuit units 251 to 254. Specifically, the selector 241 receives an output signal S131 from the processor 131. The selector 241 receives an output signal S132 from the processor 132. Further, the selector 241 receives a control signal C241 included in the control signal C24 from the controller 200. The selector 241 selects the output signal S131 or the output signal S132 in accordance with the control signal C241. The selector 241 is connected to the circuit unit 251 for allowing transmission of signals. The selector 241 outputs the selected signal to the circuit unit 251 as a selection signal S241.

The selector 242 receives the output signal S132 from the processor 132. The selector 242 receives an output signal S133 from the processor 133. Further, the selector 242 receives a control signal C242 included in the control signal C24 from the controller 200. The selector 242 selects the output signal S132 or the output signal S133 according to the control signal C242. The selector 242 is connected to the circuit unit 252 for allowing transmission of signals. The selector 242 outputs the selected signal to the circuit unit 252 as a selection signal S242.

The selector 243 receives the output signal S133 from the processor 133. The selector 243 receives an output signal S134 from the processor 134. Further, the selector 243 receives a control signal C243 included in the control signal C24 from the controller 200. The selector 243 selects the output signal S133 or the output signal S134 according to the control signal C243. The selector 243 is connected to the circuit unit 253 for allowing transmission of signals. The selector 243 outputs the selected signal to the circuit unit 253 as a selection signal S243.

The selector 244 receives the output signal S134 from the processor 134. In addition, the selector 244 receives an output signal S135 from the redundant processor 135. Further, the selector 244 receives a control signal C244 included in the control signal C24 from the controller 200. The selector 244 selects the output signal S134 or the output signal S135 in accordance with the control signal C244. The selector 244 is connected to the circuit unit 254 for allowing transmission of signals. The selector 244 outputs the selected signal to the circuit unit 254 as a selection signal S244.

Each of the circuit units 251 to 254 includes a combinational circuit, a sequential circuit, and the like. The circuit units 251 to 254 perform predetermined signal processing on input data. The circuit units 251 to 254 output data after the signal processing. Specifically, the circuit unit 251 receives the selection signal S241 from the selector 241. The circuit unit 251 performs predetermined signal processing on the selection signal S241 and outputs data after the signal processing. The circuit unit 252 receives the selection signal S242 from the selector 242. The circuit unit 252 performs predetermined signal processing on the selection signal S242 and outputs data after the signal processing. The circuit unit 253 receives the selection signal S243 from the selector 243. The circuit unit 253 performs predetermined signal processing on the selection signal S243, and outputs data after the signal processing. The circuit unit 254 receives the selection signal S244 from the selector 244. The circuit unit 254 performs predetermined signal processing on the selection signal S244, and outputs data after the signal processing.

### Generation of Test Patterns

The controllers 100 and 200 of the semiconductor devices 11 and 21 according to the present disclosure generate multiple test patterns for executing a scan test on the processors 131 to 134 according to the setting signals S109 and S219. In the present embodiment, the controller 100 generates five test patterns. The scan test using the test patterns is realized by controlling the operations of the selectors 121 to 123, the selectors 141 to 144, the selectors 151 to 154, the selectors 221 to 223, and the selectors 241 to 244 using the control signals C12, C14, C15, C22, and C24. The five test patterns generated by the controller 100 of the semiconductor device 11 will be described below with reference to FIG. 1.

### First Test Pattern

In the first test pattern, the output signal S131 and the output signal S160, which correspond to the results of the scan test for the processor 131 and the circuit unit 160, are output to the scan compressor 170. On the other hand, in the first test pattern, the output signals S132 to S135, which correspond to the results of the scan test for the processors 132 to 134 and the redundant processor 135, are not output to the scan compressor 170.

In order to execute the scan test according to the first test pattern, the controller 100 sets the control signals C12, C14, and C15 to predetermined values, respectively, and outputs these control signals to the selectors 121 to 123, the selectors 141 to 144, and the selectors 151 to 154, respectively. Specifically, in order to output the result of the scan test for the processor 131 to the scan compressor 170, the controller 100 sets the control signal C141 for allowing the selector 141 to output the output signal S131 to the selector 151 as the selection signal S141. In addition, the controller 100 sets the control signal C151 for allowing the selector 151 to output the selection signal S141 corresponding to the output signal S131 to the scan compressor 170 as the selection signal S151.

On the other hand, in the first test pattern, the output signals S132 to S135 are not output to the scan compressor 170, and the pattern signals S112 to S114 are output to the scan compressor 170. Specifically, the controller 100 sets the control signal C121 for allowing the selector 121 to output the pattern signal S112 as the selection signal S121 to the selector 142 via the bypass 132B. In addition, the controller 100 sets the control signal C142 for allowing the selector 142 to output the selection signal S121 corresponding to the pattern signal S112 to the selector 152 as the selection signal S142. Further, the controller 100 sets the control signal C152 for allowing the selector 152 to output the selection signal S142 corresponding to the pattern signal S112 to the scan compressor 170 as the selection signal S152.

In addition, the controller 100 sets the control signal C122 for allowing the selector 122 to output the pattern signal S113 as the selection signal S122 to the selector 143 via the bypass 133B. In addition, the controller 100 sets the control signal C143 for allowing the selector 143 to output the selection signal S122 corresponding to the pattern signal S113 to the selector 153 as the selection signal S143. Further, the controller 100 sets the control signal C153 for allowing the selector 153 to output the selection signal S143 corresponding to the pattern signal S113 to the scan compressor 170 as the selection signal S153. Similarly, the controller 100 sets the control signal C123 for allowing the selector 123 to output the pattern signal S114 as the selection signal S123 to the selector 144 via the bypass 134B. In addition, the controller 100 sets the control signal C144 for allowing the selector 144 to output the selection signal S123 corresponding to the pattern signal S114 to the selector 154 as the selection signal S144. Further, the controller 100 sets the control signal C154 for allowing the selector 154 to output the selection signal S144 corresponding to the pattern signal S114 to the scan compressor 170 as the selection signal S154.

### Second Test Pattern

In the second test pattern, the output signal S132 and the output signal S160, which correspond to the results of the scan test for the processor 132 and the circuit unit 160, are output to the scan compressor 170. On the other hand, in the second test pattern, the output signals S131, S133, S134, and S135, which correspond to the results of the scan test for the processors 131, 133, and 134 and the redundant processor 135, are not output to the scan compressor 170.

In order to execute the scan test according to the second test pattern, the controller 100 sets the control signals C12, C14, and C15 to predetermined values, respectively, and outputs these control signals to the selectors 121 to 123, the selectors 141 to 144, and the selectors 151 to 154, respectively. Specifically, in order to output the result of the scan test for the processor 132 to the scan compressor 170, the controller 100 sets the control signal C121 for allowing the selector 121 to output the pattern signal S112 to the processor 132 as the selection signal S121. In addition, the controller 100 sets the control signal C142 for allowing the selector 142 to output the output signal S132 to the selector 152 as the selection signal S142. Further, the controller 100 sets the control signal C152 for allowing the selector 152 to output the selection signal S142 corresponding to the output signal S132 to the scan compressor 170 as the selection signal S152.

On the other hand, in the second test pattern, the output signals S131, S133, S134, and S135 are not output to the scan compressor 170, and the pattern signals S111, S113, and S114 are output to the scan compressor 170. Specifically, the controller 100 sets the control signal C141 for allowing the selector 141 to output the pattern signal S111 input via the bypass 131B to the selector 151 as the selection signal S141. Further, the controller 100 sets the control signal C151 for allowing the selector 151 to output the selection signal S141 corresponding to the pattern signal S111 to the scan compressor 170 as the selection signal S151.

In addition, the controller 100 sets the control signal C122 for allowing the selector 122 to output the pattern signal S113 as the selection signal S122 to the selector 143 via the bypass 133B. In addition, the controller 100 sets the control signal C143 for allowing the selector 143 to output the selection signal S122 corresponding to the pattern signal S113 to the selector 153 as the selection signal S143. Further, the controller 100 sets the control signal C153 for allowing the selector 153 to output the selection signal S143 corresponding to the pattern signal S113 to the scan compressor 170 as the selection signal S153. Similarly, the controller 100 sets the control signal C123 for allowing the selector 123 to output the pattern signal S114 as the selection signal S123 to the selector 144 via the bypass 134B. In addition, the controller 100 sets the control signal C144 for allowing the selector 144 to output the selection signal S123 corresponding to the pattern signal S114 to the selector 154 as the selection signal S144. Further, the controller 100 sets the control signal C154 for allowing the selector 154 to output the selection signal S144 corresponding to the pattern signal S114 to the scan compressor 170 as the selection signal S154.

### Third Test Pattern

In the third test pattern, the output signal S133 and the output signal S160, which correspond to the results of the scan test for the processor 133 and the circuit unit 160, are output to the scan compressor 170. On the other hand, in the third test pattern, the output signals S131, S132, S134, and S135, which correspond to the results of the scan test for the processors 131, 132, and 134 and the redundant processor 135, are not output to the scan compressor 170.

In order to execute the scan test according to the third test pattern, the controller 100 sets the control signals C12, C14, and C15 to predetermined values, respectively, and outputs these control signals to the selectors 121 to 123, the selectors 141 to 144, and the selectors 151 to 154, respectively. Specifically, in order to output the result of the scan test for the processor 133 to the scan compressor 170, the controller 100 sets the control signal C122 for allowing the selector 122 to output the pattern signal S113 to the processor 133 as the selection signal S122. In addition, the controller 100 sets the control signal C143 for allowing the selector 143 to output the output signal S133 to the selector 153 as the selection signal S143. Further, the controller 100 sets the control signal C153 for allowing the selector 153 to output the selection signal S143 corresponding to the output signal S133 to the scan compressor 170 as the selection signal S153.

On the other hand, in the third test pattern, the output signals S131, S132, S134, and S135 are not output to the scan compressor 170, and the pattern signals S111, S112, and S114 are output to the scan compressor 170. Specifically, the controller 100 sets the control signal C141 for allowing the selector 141 to output the pattern signal S111 input via the bypass 131B to the selector 151 as the selection signal S141. Further, the controller 100 sets the control signal C151 for allowing the selector 151 to output the selection signal S141 corresponding to the pattern signal S111 to the scan compressor 170 as the selection signal S151.

In addition, the controller 100 sets the control signal C121 for allowing the selector 121 to output the pattern signal S112 as the selection signal S121 to the selector 142 via the bypass 132B. In addition, the controller 100 sets the control signal C142 for allowing the selector 142 to output the selection signal S121 corresponding to the pattern signal S112 to the selector 152 as the selection signal S142. Further, the controller 100 sets the control signal C152 for allowing the selector 152 to output the selection signal S142 corresponding to the pattern signal S112 to the scan compressor 170 as the selection signal S152. Similarly, the controller 100 sets the control signal C123 for allowing the selector 123 to output the pattern signal S114 as the selection signal S123 to the selector 144 via the bypass 134B. In addition, the controller 100 sets the control signal C144 for allowing the selector 144 to output the selection signal S123 corresponding to the pattern signal S114 to the selector 154 as the selection signal S144. Further, the controller 100 sets the control signal C154 for allowing the selector 154 to output the selection signal S144 corresponding to the pattern signal S114 to the scan compressor 170 as the selection signal S154.

### Fourth Test Pattern

In the fourth test pattern, the output signal S134 and the output signal S160, which correspond to the results of the scan test for the processor 134 and the circuit unit 160, are output to the scan compressor 170. On the other hand, in the fourth test pattern, the output signals S131 to S133 and S135, which correspond to the results of the scan test for the processors 131 to 133 and the redundant processor 135, are not output to the scan compressor 170.

In order to execute the scan test according to the fourth test pattern, the controller 100 sets the control signals C12, C14, and C15 to predetermined values, respectively, and outputs these control signals to the selectors 121 to 123, the selectors 141 to 144, and the selectors 151 to 154, respectively. Specifically, in order to output the result of the scan test for the processor 134 to the scan compressor 170, the controller 100 sets the control signal C123 for allowing the selector 123 to output the pattern signal S114 to the processor 134 as the selection signal S123. In addition, the controller 100 sets the control signal C144 for allowing the selector 144 to output the output signal S134 to the selector 154 as the selection signal S144. Further, the controller 100 sets the control signal C154 for allowing the selector 154 to output the selection signal S144 corresponding to the output signal S134 to the scan compressor 170 as the selection signal S154.

On the other hand, in the fourth test pattern, the output signals S131 to S133 and S135 are not output to the scan compressor 170, and the pattern signals S111 to S113 are output to the scan compressor 170. Specifically, the controller 100 sets the control signal C141 for allowing the selector 141 to output the pattern signal S111 input via the bypass 131B to the selector 151 as the selection signal S141. Further, the controller 100 sets the control signal C151 for allowing the selector 151 to output the selection signal S141 corresponding to the pattern signal S111 to the scan compressor 170 as the selection signal S151.

In addition, the controller 100 sets the control signal C121 for allowing the selector 121 to output the pattern signal S112 as the selection signal S121 to the selector 142 via the bypass 132B. In addition, the controller 100 sets the control signal C142 for allowing the selector 142 to output the selection signal S121 corresponding to the pattern signal S112 to the selector 152 as the selection signal S142. Further, the controller 100 sets the control signal C152 for allowing the selector 152 to output the selection signal S142 corresponding to the pattern signal S112 to the scan compressor 170 as the selection signal S152. Similarly, the controller 100 sets the control signal C122 for allowing the selector 122 to output the pattern signal S113 as the selection signal S122 to the selector 143 via the bypass 133B. In addition, the controller 100 sets the control signal C143 for allowing the selector 143 to output the selection signal S122 corresponding to the pattern signal S113 to the selector 153 as the selection signal S143. Further, the controller 100 sets the control signal C153 for allowing the selector 153 to output the selection signal S143 corresponding to the pattern signal S113 to the scan compressor 170 as the selection signal S153.

### Fifth Test Pattern

In the fifth test pattern, the pattern signals S111 to S114 are output to the processors 131 to 134 or the redundant processor 135 according to the control signals C12, C14, and C15, respectively. The pattern signal S115 is output to the circuit unit 160. In accordance with the input pattern signals S111 to S114, the processors 131 to 134 and the redundant processor 135 output the output signals S131 to S135 to the scan compressor 170. The circuit unit 160 outputs the output signal S160 to the scan compressor 170. In the fifth test pattern, the pattern signals S111 to S114 are output to the scan compressor 170 via any of the processors 131 to 134 and the redundant processor 135. That is, in the fifth test pattern, the pattern signals S111 to S114 are not output to the scan compressor 170 through the bypasses 131B to 134B.

In order to execute the scan test according to the fifth test pattern, the controller 100 sets the control signals C12, C14, and C15 to predetermined values, respectively, and outputs these control signals to the selectors 121 to 123, the selectors 141 to 144, and the selectors 151 to 154, respectively. Specifically, in order to output the result of the scan test for the processor 131 to the scan compressor 170, the controller 100 sets the control signal C141 for allowing the selector 141 to output the output signal S131 to the selector 151 as the selection signal S141. In addition, the controller 100 sets the control signal C151 for allowing the selector 151 to output the selection signal S141 corresponding to the output signal S131 to the scan compressor 170 as the selection signal S151.

In addition, in order to output the result of the scan test for the processor 132 to the scan compressor 170, the controller 100 sets the control signal C121 for allowing the selector 121 to output the pattern signal S112 to the processor 132 as the selection signal S121. Further, the controller 100 sets the control signal C142 for allowing the selector 142 to output the output signal S132 to the selector 152 as the selection signal S142. Further, the controller 100 sets the control signal C152 for allowing the selector 152 to output the selection signal S142 corresponding to the output signal S132 to the scan compressor 170 as the selection signal S152.

Further, in order to output the result of the scan test for the processor 133 to the scan compressor 170, the controller 100 sets the control signal C122 for allowing the selector 122 to output the pattern signal S113 to the processor 133 as the selection signal S122. In addition, the controller 100 sets the control signal C143 for allowing the selector 143 to output the output signal S133 to the selector 153 as the selection signal S143. Further, the controller 100 sets the control signal C153 for allowing the selector 153 to output the selection signal S143 corresponding to the output signal S133 to the scan compressor 170 as the selection signal S153.

In addition, in order to output the result of the scan test for the processor 134 to the scan compressor 170, the controller 100 sets the control signal C123 for allowing the selector 123 to output the pattern signal S114 to the processor 134 as the selection signal S123. In addition, the controller 100 sets the control signal C144 for allowing the selector 144 to output the output signal S134 to the selector 154 as the selection signal S144. Further, the controller 100 sets the control signal C154 for allowing the selector 154 to output the selection signal S144 corresponding to the output signal S134 to the scan compressor 170 as the selection signal S154.

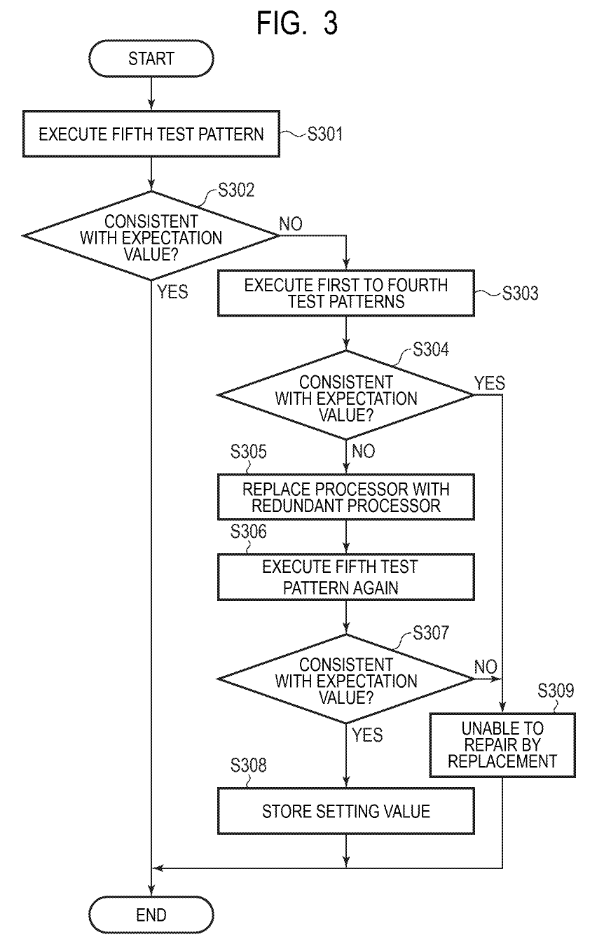

According to the present embodiment, the scan test is executed using the first to fifth test patterns when the operation of the semiconductor device is inspected or verified by the tester, and a processor having a failure is identified based on the result of the scan test. A specific procedure for identifying a processor having a failure will be described below with reference to FIGS. 1 and 3. FIG. 3 is a flowchart showing a procedure of identifying a processor having a failure and replacing the processor with a redundant processor of the semiconductor device according to the present embodiment.

In step S301, a scan test using the fifth test pattern is performed on the semiconductor device 11. That is, in step S301, the selectors 151 to 154 output the selection signals S151 to S154 corresponding to the output signals S131 to S134 to the scan compressor 170. The scan compressor outputs the output signal S170 to a tester based on the selection signals S151 to S154.

In step S302, the tester compares the output signal S170 with an expected value (expectation value) of the scan test using the fifth test pattern, and determines whether the output signal S170 matches or is consistent with the expectation value. If determined that the output signal S170 matches or is consistent with the expectation value (YES in step S302), the tester determines that the processors 131 to 134 operate normally, and ends the process of the flowchart. On the other hand, if determined that the output signal S170 does not match or is inconsistent with the expectation value (NO in step S302), the tester determines that it is possible that at least one of processors 131 to 134 has a failure, and advances the process to step S303.

In step S303, scan tests using the first to fourth test patterns are sequentially performed on the semiconductor device 11. Specifically, for example, a scan test using the first test pattern is first executed. The selector 151 outputs the selection signal S151 corresponding to the output signal S131 to the scan compressor 170. On the other hand, the selectors 152 to 154 output the selection signals S152 to S154 corresponding to the pattern signals S112 to S114, respectively, to the scan compressor 170. That is, in the scan test using the first test pattern, the output signals S132 to S134 of the processors 132 to 134 other than the processor 131 are not output to the scan compressor 170. The scan compressor 170 outputs the output signal S170 to the tester based on the selection signals S151 to S154. Then, a scan test using the second test pattern is executed. The selector 152 outputs the selection signal S152 corresponding to the output signal S132 to the scan compressor 170. On the other hand, the selectors 151, 153, and 154 output the selection signals S151, S153, and S154 corresponding to the pattern signals S111, S113, and S114, respectively, to the scan compressor 170. That is, in the scan test using the second test pattern, the output signals S131, S133, and S134 of the processors 131, 133, and 134 other than the processor 132 are not output to the scan compressor 170. The scan compressor 170 outputs the output signal S170 to the tester based on the selection signals S151 to S154.

Then, a scan test using the third test pattern is executed. The selector 153 outputs the selection signal S153 corresponding to the output signal S133 to the scan compressor 170. On the other hand, the selectors 151, 152, and 154 output the selection signals S151, S152, and S154 corresponding to the pattern signals S111, S112, and S114, respectively, to the scan compressor 170. That is, in the scan test using the third test pattern, the output signals S131, S132, and S134 of the processors 131, 132, and 134 other than the processor 133 are not output to the scan compressor 170. The scan compressor 170 outputs the output signal S170 to the tester based on the selection signals S151 to S154. Finally, a scan test using the fourth test pattern is executed. The selector 154 outputs the selection signal S154 corresponding to the output signal S134 to the scan compressor 170. On the other hand, the selectors 151 to 153 output the selection signals S151 to S153 respectively corresponding to the pattern signals S111 to S113 to the scan compressor 170. That is, in the scan test using the fourth test pattern, the output signals S131 to S133 of the processors 131 to 133 other than the processor 134 are not output to the scan compressor 170. The scan compressor 170 outputs the output signal S170 to the tester based on the selection signals S151 to S154. That is, in step S303, the scan tests using the multiple test patterns are repeatedly executed the number of times corresponding to the number of processors 131 to 134. After the scan test using the fourth test pattern is completed, the process proceeds to step S304.

In step S304, the tester compares the output signal S170 indicating the result of the scan test using the first to fourth test patterns with the expectation value corresponding to the first to fourth scan patterns, and determines whether or not the output signal S170 matches the expectation value. If determined that all the output signals S170 obtained by the first to fourth test patterns respectively match or are consistent with the corresponding expectation values (YES in step S304), the tester determines that the processors 131 to 134 operate normally, and proceeds to step S309. In step S309, the tester determines that the semiconductor device 11 has a defect due to a cause other than the failure of the processors 131 to 134. That is, the tester determines that the defect of the semiconductor device 11 cannot be fixed or recovered by using the redundant processor 135. The semiconductor device 11 having the defect is discarded as being unrecoverable, and the processing according to the flowchart is ended.

On the other hand, in step S304, if determined that any of the output signals S170 obtained by the first to fourth test patterns does not match or is inconsistent with the expectation value (NO in step S304), the tester determines that the processor that outputs the output signal related to the inconsistent output signal S170 has a failure, and the process is advanced to step S305.

In step S305, the controller 100 controls the selectors 121 to 123, the selectors 141 to 144, and the selectors 151 to 154 via the control signals C12, C14, and C15 so as to perform signal processing using the redundant processor instead of the processor determined to have a failure. As an example, the operation of the controller 100 in a case where it is determined that the processor 132 has a failure will be described below with reference to FIG. 1.

The processor 131 receives the pattern signal S111, the processor 133 receives the pattern signal S112, the processor 134 receives the pattern signal S113, and the redundant processor 135 receives the pattern signal S114. The selector 151 outputs the selection signal S151 corresponding to the output signal S131, the selector 152 outputs the selection signal S152 corresponding to the output signal S133, the selector 153 outputs the selection signal S153 corresponding to the output signal S134, and the selector 154 outputs the selection signal S154 corresponding to the output signal S135. The output signal S132 of the processor 132 having a failure is not output to the scan compressor 170.

In order to replace the processor 132 with the redundant processor 135 as described above, the controller 100 sets the control signal C122 for allowing the selector 122 to output the pattern signal S112 to the processor 133 as the selection signal S122. In addition, the controller 100 sets the control signal C143 for allowing the selector 143 to output the output signal S133 to the selector 152 as the selection signal S143. Further, the controller 100 sets the control signal C152 for allowing the selector 152 to output the selection signal S143 corresponding to the output signal S133 to the scan compressor 170 as the selection signal S152.

In addition, the controller 100 sets the control signal C123 for allowing the selector 123 to output the pattern signal S113 to the processor 134 as the selection signal S123. In addition, the controller 100 sets the control signal C144 for allowing the selector 144 to output the output signal S134 to the selector 153 as the selection signal S144. Further, the controller 100 sets the control signal C153 for allowing the selector 153 to output the selection signal S144 corresponding to the output signal S134 to the scan compressor 170 as the selection signal S153.

Further, the controller 100 sets the control signal C154 for allowing the selector 154 to output the output signal S135 to the scan compressor 170 as the selection signal S154. In addition, the controller 100 sets the control signal C141 for allowing the selector 141 to output the output signal S131 to the selector 151 as the selection signal S141. Further, the controller 100 sets the control signal C151 for allowing the selector 151 to output the selection signal S141 corresponding to the output signal S131 to the scan compressor 170 as the selection signal S151. Setting the control signals C12, C14, and C15 as described above allows to avoid using the processor 132 having a failure, and alternatively, to cause the redundant processor 135 having the circuit configuration logically equivalent to the processor 132 to perform signal processing. Replacing a processor having a failure with the redundant processor 135 allows to suppress a decrease in yield of the semiconductor device 11 caused by the failure or malfunction of the processor.

Here, as an example, the operation of the controller 200 in a case where it is determined that the processor 132 has a failure will be described with reference to FIG. 2.

The processor 131 receives the data signal S211, and the processor 133 receives the data signal S212. The processor 134 receives the data signal S213, and the redundant processor 135 receives the data signal S214. The selector 241 outputs the selection signal S241 corresponding to the output signal S131, and the selector 242 outputs the selection signal S242 corresponding to the output signal S133. The selector 243 outputs the selection signal S243 corresponding to the output signal S134, and the selector 244 outputs the selection signal S244 corresponding to the output signal S135. The output signal S132 of the processor 132 having a failure is not output to the circuit units 251 to 254.

As described above, in order to replace the processor 132 with the redundant processor 135, the controller 200 sets the control signal C222 for allowing the selector 222 to output the data signal S212 to the processor 133 as the selection signal S222. In addition, the controller 200 sets the control signal C242 for allowing the selector 242 to output the output signal S133 to the circuit unit 252 as the selection signal S242.

In addition, the controller 200 sets the control signal C223 for allowing the selector 223 to output the data signal S213 to the processor 134 as the selection signal S223. In addition, the controller 200 sets the control signal C143 for allowing the selector 243 to output the output signal S134 to the circuit unit 253 as the selection signal S243.

Further, the controller 200 sets the control signal C244 for allowing the selector 244 to output the output signal S135 to the circuit unit 254 as the selection signal S244. In addition, the controller 200 sets the control signal C241 for allowing the selector 241 to output the output signal S131 to the circuit unit 251 as the selection signal S241. Setting the control signals C22 and C24 as described above allows to avoid using the processor 132 having a failure, and alternatively, to cause the redundant processor 135 having the circuit configuration logically equivalent to the processor 132 to perform signal processing. Replacing a processor having a failure with the redundant processor 135 allows to suppress a decrease in yield of the semiconductor device 21 caused by the failure or malfunction of the processor.

In step S306, the scan test using the fifth test pattern is executed again on the semiconductor device 11. That is, in an example in which the processor 132 has a failure, the selectors 151 to 154 output the selection signals S151 to S154 corresponding to the output signals S131 and S133 to S135 to the scan compressor 170. The scan compressor 170 outputs the output signal S170 to the tester based on the selection signals S151 to S154.

In step S307, the tester compares the output signal S170 with the expectation value of the scan test using the fifth test pattern, and determines whether or not the output signal S170 matches or is consistent with the expectation value. If determined that the output signal S170 matches or is consistent with the expectation value (YES in step S307), the tester determines that the processors 131, 133, and 134 and the redundant processor 135 operate normally, and the process is advanced to step S308. On the other hand, if determined that the output signal S170 does not match or is inconsistent with the expectation value (NO in step S307), the tester determines that the semiconductor device 11 does not operate normally even after replacing the processor 132 having a failure with the redundant processor 135, and the process proceeds to step S309.

In step S308, the semiconductor device 11 stores the setting values of the control signals C12, C14, and C15 used for substituting the redundant processor 135 for the processor 132 that has a failure. For example, the semiconductor device 11 stores or overwrites the modified setting values of the control signals C12, C14, and C15 in a nonvolatile memory or the like in which the initial setting values of the control signals C12, C14, and C15 are stored. In a case where the semiconductor device 11 has an electronic fuse (eFuse) with a built-in MOSFET or the like, the modified setting values of the control signals C12, C14, and C15 may be stored in the eFuse. After the modified setting values of the control signals C12, C14, and C15 are stored, the processing according to the flowchart is ended.

Advancing the scaling of the semiconductor processes allows to integrate a large number of transistors on a chip. On the other hand, with the advancement of the scaling of the semiconductor processes, the manufacturing process of semiconductor devices is becoming increasingly complicated. The complication of the manufacturing process increases causes of generating minute defects in the semiconductor devices. The generation of minute defects in the semiconductor device causes a decrease in yield. In a case where a failure of a processor is detected in a test executed before shipping a semiconductor device, the processor having a failure is generally replaced with another processor to improve the yield of the semiconductor devices.

In order to improve the yield of the semiconductor devices, it is necessary to identify a processor having a failure. Conventionally, analyzing the result of the obtained scan test is required to identify a processor having a failure. Since the analysis takes a lot of time, the time required for the operation test of the semiconductor devices drastically increases as the scaling of the semiconductor processes progresses.

According to the present disclosure, it is possible to easily identify a processor having a failure by executing a scan test on the processors using multiple test patterns. That is, it is no longer necessary to perform the analysis of test results that takes a lot of time to identify a processor having a failure, which has been conventionally performed. Therefore, according to the present disclosure, it is possible to improve the yield while reducing the cost required for the test for checking the operation of the semiconductor devices.

### Second Embodiment

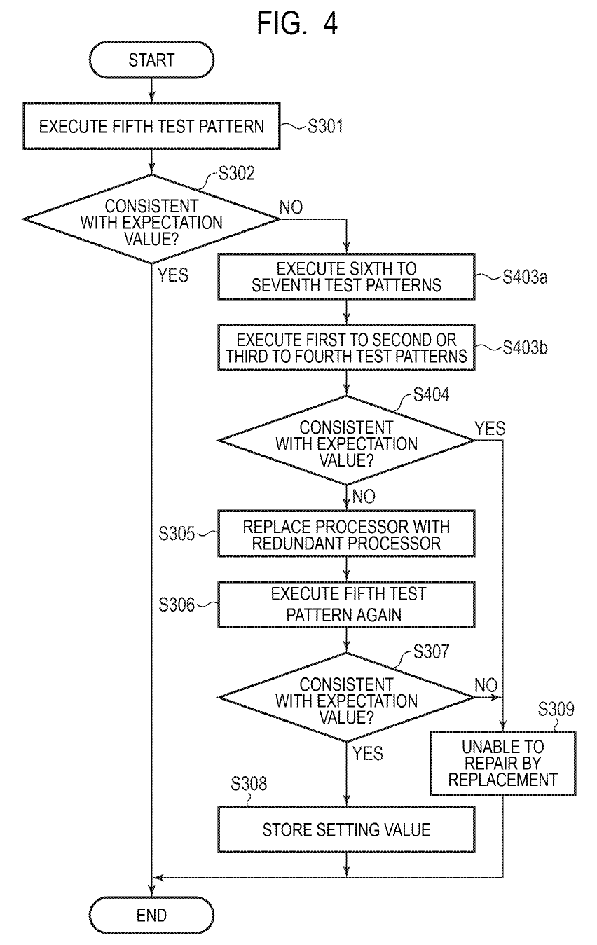

A procedure for identifying a processor having a failure using the method according to the second embodiment will be described below with reference to FIGS. 1 and 4. FIG. 4 is a flowchart showing the procedure of identifying a processor having a failure and replacing the processor with a redundant processor of the semiconductor device according to the present embodiment. In FIG. 4, steps other than steps S403a, S403b, and S404 are the same as those in FIG. 3. Therefore, descriptions of the steps other than steps S403a, S403b, and S404 will be omitted.

The method according to the present embodiment is different from the first embodiment in that multiple processors are divided into a group of processors, a scan test is recursively performed on the respective groups of processors, and a processor having a failure is identified.

In the present embodiment, if the output signal S170 indicating the result of the scan test using the fifth test pattern does not match or is inconsistent with the expectation value (NO in step S302), the tester determines that it is possible that at least one of the processors 131 to 134 has a failure, and advances the process to step S403a.

In step S403a, scan tests using the sixth to seventh test patterns are sequentially performed on the semiconductor device 11. The sixth test pattern is used to perform a scan test on a group including the processor 131 and the processor 132. The seventh test pattern is used to perform a scan test on a group including the processor 133 and the processor 134. The sixth test pattern and the seventh test pattern will be described below.

### Sixth Test Pattern

In the sixth test pattern, the output signals S131, S132, and S160, which correspond to the results of the scan test for the processor 131, the processor 132, and the circuit unit 160, are output to the scan compressor 170. On the other hand, in the sixth test pattern, the output signals S133 to S135, which correspond to the results of the scan test for the processor 133, the processor 134, and the redundant processor 135, are not output to the scan compressor 170.

In order to execute the scan test according to the sixth test pattern, the controller 100 sets the control signals C12, C14, and C15 to predetermined values, respectively, and outputs these control signals to the selectors 121 to 123, the selectors 141 to 144, and the selectors 151 to 154, respectively. Specifically, in order to output a result of the scan test for the processor 131 to the scan compressor 170, the controller 100 sets the control signal C141 for allowing the selector 141 to output the output signal S131 to the selector 151 as the selection signal S141. In addition, the controller 100 sets the control signal C151 for allowing the selector 151 to output the selection signal S141 corresponding to the output signal S131 to the scan compressor 170 as the selection signal S151.

In addition, in order to output a result of the scan test for the processor 132 to the scan compressor 170, the controller 100 sets the control signal C121 for allowing the selector 121 to output the pattern signal S112 to the processor 132 as the selection signal S121. In addition, the controller 100 sets the control signal C142 for allowing the selector 142 to output the output signal S132 to the selector 152 as the selection signal S142. Further, the controller 100 sets the control signal C152 for allowing the selector 152 to output the selection signal S142 corresponding to the output signal S132 to the scan compressor 170 as the selection signal S152.

On the other hand, in the sixth test pattern, the output signals S133 to S135 are not output to the scan compressor 170, and the pattern signal S113 and the pattern signal S114 are output to the scan compressor 170. Specifically, the controller 100 sets the control signal C122 for allowing the selector 122 to output the pattern signal S113 as the selection signal S122 to the selector 143 via the bypass 133B. In addition, the controller 100 sets the control signal C143 for allowing the selector 143 to output the selection signal S122 corresponding to the pattern signal S113 to the selector 153 as the selection signal S143. Further, the controller 100 sets the control signal C153 for allowing the selector 153 to output the selection signal S143 corresponding to the pattern signal S113 to the scan compressor 170 as the selection signal S153. Similarly, the controller 100 sets the control signal C123 for allowing the selector 123 to output the pattern signal S114 as the selection signal S123 to the selector 144 via the bypass 134B. In addition, the controller 100 sets the control signal C144 for allowing the selector 144 to output the selection signal S123 corresponding to the pattern signal S114 to the selector 154 as the selection signal S144. Further, the controller 100 sets the control signal C154 for allowing the selector 154 to output the selection signal S144 corresponding to the pattern signal S114 to the scan compressor 170 as the selection signal S154.

### Seventh Test Pattern

In the seventh test pattern, the output signals S133, S134, and S160, which correspond to the results of the scan test for the processor 133, the processor 134, and the circuit unit 160, are output to the scan compressor 170. On the other hand, in the sixth test pattern, the output signals S131, S132, and S135, which correspond to the results of the scan test for the processor 131, the processor 132, and the redundant processor 135, are not output to the scan compressor 170.

In order to execute the scan test according to the seventh test pattern, the controller 100 sets the control signals C12, C14, and C15 to predetermined values, respectively, and outputs these control signals to the selectors 121 to 123, the selectors 141 to 144, and the selectors 151 to 154, respectively. Specifically, in order to output a result of the scan test for the processor 133 to the scan compressor 170, the controller 100 sets the control signal C122 for allowing the selector 122 to output the pattern signal S113 to the processor 133 as the selection signal S122. In addition, the controller 100 sets the control signal C143 for allowing the selector 143 to output the output signal S133 to the selector 153 as the selection signal S143. Further, the controller 100 sets the control

signal C153 for allowing the selector 153 to output the selection signal S143 corresponding to the output signal S133 to the scan compressor 170 as the selection signal S153.

In addition, in order to output a result of the scan test for the processor 134 to the scan compressor 170, the controller 100 sets the control signal C123 for allowing the selector 123 to output the pattern signal S114 to the processor 134 as the selection signal S123. In addition, the controller 100 sets the control signal C144 for allowing the selector 144 to output the output signal S134 to the selector 154 as the selection signal S144. Further, the controller 100 sets the control signal C154 for allowing the selector 154 to output the selection signal S144 corresponding to the output signal S134 to the scan compressor 170 as the selection signal S154.

On the other hand, in the seventh test pattern, the output signals S131, S132, and S135 are not output to the scan compressor 170, and the pattern signal S111 and the pattern signal S112 are output to the scan compressor 170. Specifically, the controller 100 sets the control signal C141 for allowing the selector 141 to output the pattern signal S111 input via the bypass 131B to the selector 151 as the selection signal S141. Further, the controller 100 sets the control signal C151 for allowing the selector 151 to output the selection signal S141 corresponding to the pattern signal S111 to the scan compressor 170 as the selection signal S151. In addition, the controller 100 sets the control signal C121 for allowing the selector 121 to output the pattern signal S112 as the selection signal S121 to the selector 142 via the bypass 132B. In addition, the controller 100 sets the control signal C142 for allowing the selector 142 to output the selection signal S121 corresponding to the pattern signal S112 to the selector 152 as the selection signal S142. Further, the controller 100 sets the control signal C152 for allowing the selector 152 to output the selection signal S142 corresponding to the pattern signal S112 to the scan compressor 170 as the selection signal S152.

In step S403a, for example, a scan test using the sixth test pattern is first executed. The selector 151 and the selector 152 output the selection signals S151 and S152 corresponding to the output signal S131 and the output signal S132, respectively, to the scan compressor 170. On the other hand, the selector 153 and the selector 154 output the selection signal S153 and the selection signal S154 corresponding to the pattern signal S113 and the pattern signal S114, respectively, to the scan compressor 170. The scan compressor 170 outputs the output signal S170 to the tester based on the selection signals S151 to S154. Then, a scan test using the seventh test pattern is executed. The selector 153 and the selector 154 output the selection signal S153 and the selection signal S154 corresponding to the output signal S133 and the output signal S134, respectively, to the scan compressor 170. On the other hand, the selector 151 and the selector 152 output the selection signal S151 and the selection signal S152 corresponding to the pattern signal S111 and the pattern signal S112, respectively, to the scan compressor 170. The scan compressor 170 outputs the output signal S170 to the tester based on the selection signals S151 to S154.

In a case where the output signal S170 obtained by the sixth test pattern does not match or is inconsistent with the expectation value, the tester determines that the processor 131 or the processor 132 that has output a signal related to the output signal S170 has a failure. In a case where the output signal S170 obtained by the seventh test pattern does not match or is inconsistent with the expectation value, the tester determines that the processor 133 or the processor 134 that has output a signal related to the output signal S170 has a failure. Hereinafter, an example in which the processor 132 has a failure will be described. The tester determines that the processor 131 or the processor 132 has a failure based on the output signal S170 obtained by the sixth test pattern and the corresponding expectation value.

In step S403b, scan tests using the first test pattern and the second test pattern are sequentially performed on the semiconductor device 11. Specifically, for example, a scan test using the first test pattern is first executed. The selector 151 outputs the selection signal S151 corresponding to the output signal S131 to the scan compressor 170. On the other hand, the selectors 152 to 154 output the selection signals S152 to S154 corresponding to the pattern signals S112 to S114, respectively, to the scan compressor 170. The scan compressor 170 outputs the output signal S170 to the tester based on the selection signals S151 to S154. Then, a scan test using the second test pattern is executed. The selector 152 outputs the selection signal S152 corresponding to the output signal S132 to the scan compressor 170. On the other hand, the selectors 151, 153, and 154 output the selection signals S151, S153, and S154 corresponding to the pattern signals S111, S113, and S114, respectively, to the scan compressor 170. The scan compressor 170 outputs the output signal S170 to the tester based on the selection signals S151 to S154.

In step S404, the tester compares the output signal S170 indicating the results of the scan tests using the first and second test patterns with the corresponding expectation values, and determines whether or not the output signals S170 match or are consistent with the expectation values. If the output signals S170 obtained by the first and second test patterns respectively match or are consistent with the corresponding expectation values (YES in step S404), the tester determines that the processor 131 and the processor 132 are operating normally, and proceeds to step S309.

On the other hand, in step S404, in a case where the output signal S170 obtained by the first test pattern or the second test pattern does not match or is inconsistent with the expectation value (NO in step S404), the tester determines that the processor that outputs a signal related to the output signal S170 has a failure, and the process proceeds to step S305. In the above example, the output signal S170 obtained by the second test pattern does not match the expectation value, and the tester determines that the processor 132 that has output a signal related to the output signal S170 exhibiting inconsistency with the expectation value has a failure.

A case where the processor 133 or the processor 134 has a failure is described below. In step S403a, the tester determines that the processor 133 or the processor 134 has a failure based on the output signal S170 obtained by the seventh test pattern and the corresponding expectation value. Then, in step S403b, scan tests using the third test pattern and the fourth test pattern are sequentially executed on the semiconductor device 11. Then, in step S404, in a case where the output signal S170 obtained by the third test pattern or the fourth test pattern does not match o is inconsistent with the expectation value (NO in step S404), the tester determines that the processor that outputs a signal related to the output signal S170 has a failure, and the process proceeds to step S305. For example, in a case where the processor 134 has a failure, the output signal S170 obtained by the fourth test pattern does not match or is inconsistent with the expectation value, and the tester determines that the processor 134 that has output a signal related to the output signal S170 exhibiting inconsistency with the expectation value has a failure.

Note that the grouping of multiple processors is not limited to two divisions, and any division method can be employed. After identifying a group including a processor having a failure, the identified group may be further divided into multiple groups. Then, a group including the processor having a failure may be identified from the newly divided group. Then, the process of identifying the processor having a failure may be executed for the identified group. The number of processors included in the semiconductor device 11 is not limited to the descriptions of the present disclosure, and the number of processors may be, for example, N (N is a natural number of 2 or more). The number of processors included in one group is not limited to the descriptions of the present disclosure, and the number of processors may be, for example, M (M is a natural number smaller than N).

According to the present embodiment, recursively executing scan tests on a group including multiple processors allows to more efficiently identify a processor having a failure. The method according to the present embodiment is particularly effective in a case where there is a large number of processors to be inspected in the semiconductor device. That is, according to the present embodiment, the yield of the semiconductor devices including the highly integrated processors can be improved while further reducing the cost required for the tests for checking the operation.

### Third Embodiment

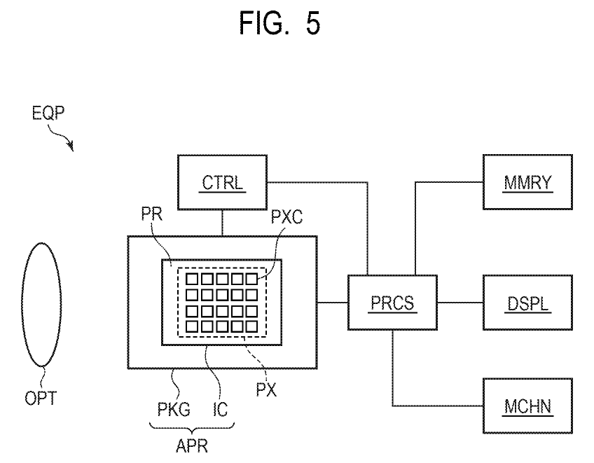

Equipment according to a third embodiment will be described with reference to FIG. 5. FIG. 5 is a block diagram showing a schematic configuration of equipment according to the present embodiment.

FIG. 5 is a schematic diagram showing equipment EQP including a photoelectric conversion device APR. The photoelectric conversion device APR includes the semiconductor device 11 according to the first and second embodiments. All or part of the photoelectric conversion device APR is a semiconductor device IC. The photoelectric conversion device APR of this example can be used as, for example, an image sensor, an auto focus (AF) sensor, a photometric sensor, a ranging sensor, or the like. The semiconductor device IC has a pixel area PX in which pixel circuits PXC each including photoelectric conversion unit are arranged in a matrix. The semiconductor device IC may have a peripheral area PR around the pixel area PX. Circuits other than the pixel circuits can be arranged in the peripheral area PR.

The photoelectric conversion device APR may have a structure (stacked chips structure) in which a first semiconductor chip provided with multiple photoelectric conversion units and a second semiconductor chip provided with a peripheral circuit are stacked. Each of the peripheral circuits in the second semiconductor chip may be a column circuit corresponding to a pixel column of the first semiconductor chip. Each of the peripheral circuits in the second semiconductor chip may be a matrix circuit corresponding to a pixel or a pixel block in the first semiconductor chip. For the connection between the first semiconductor chip and the second semiconductor chip, a through electrode (TSV), an inter-chip wiring by direct bonding of a conductor such as copper, a connection by a micro bump between chips, a connection by wire bonding, or the like can be employed.

The photoelectric conversion device APR may include a package PKG for mounting the semiconductor device IC in addition to the semiconductor device IC. The package PKG may include a base body to which the semiconductor device IC is fixed, a lid such as glass facing the semiconductor device IC, and a connection member such as a bonding wire or a bump for connecting a terminal provided on the base body and a terminal provided on the semiconductor device IC.

The equipment EQP may further include at least one of an optical device OPT, a control device CTRL, a processing device PRCS, a display device DSPL, a storage device MMRY, and a mechanical device MCHN. The optical device OPT corresponds to the photoelectric conversion device APR, and is, for example, a lens, a shutter, or a mirror. The control device CTRL controls the photoelectric conversion device APR, and is, for example, a semiconductor device such as an ASIC.

The processing device PRCS processes a signal output from the photoelectric conversion device APR, and constitutes an analog front end (AFE) or a digital front end (DFE). The processing device PRCS is a semiconductor device such as a central processing unit (CPU) or an application specific integrated circuit (ASIC). The display device DSPL is an EL display device, a liquid crystal display device, or the like that displays information (image) obtained by the photoelectric conversion device APR. The storage device MMRY is a magnetic device, a semiconductor device, or the like that stores information (image) obtained by the photoelectric conversion device APR. The storage device MMRY is a volatile memory such as an SRAM or a DRAM, or a nonvolatile memory such as a flash memory or a hard disk drive.

In addition, the processing device PRCS may acquire the optical flow by using the signal output from the semiconductor device 11 according to the first and second embodiments. For example, the processing device PRCS may generate a weighted correlation image based on a sine function, a weighted correlation image based on a cosine function, and a normal image, and acquire an optical flow from these three images.

The mechanical device MCHN includes a movable portion or a propulsion portion such as a motor or an engine. In the equipment EQP, a signal output from the photoelectric conversion device APR is displayed on the display device DSPL or transmitted to the outside by a communication device (not shown) included in the equipment EQP. Therefore, it is preferable that the equipment EQP further include a storage device MMRY and a processing device PRCS separately from the storage circuit unit and the arithmetic circuit unit included in the photoelectric conversion device APR. The mechanical device MCHN may be controlled based on a signal output from the photoelectric conversion device APR.

The equipment EQP shown in FIG. 5 may be an electronic device such as an information terminal (for example, a smartphone and a wearable terminal) having a photographing function, a camera (For example, an interchangeable lens camera, a compact camera, a video camera, and a surveillance camera), or the like. The mechanical device MCHN in the camera may drive parts of the optical device OPT for zooming, focusing, and shutter operation. Also, the equipment EQP may be a transport device (movable body) such as a vehicle, a ship, a drone, or an airplane. The equipment EQP may be a medical device such as an endoscope or a CT scanner. The equipment EQP may be a measurement device such as a ranging sensor, an analysis device such as an electron microscope, an office device such as a copier, or an industrial device such as a robot.

The mechanical device MCHN in the transport device may be used as a movable device. The equipment EQP as a transport device is suitable for transporting the photoelectric conversion device APR, or for assisting and/or automating driving (manipulation) by an imaging function. The processing device PRCS for assisting and/or automating driving (manipulation) may perform processing for operating the mechanical device MCHN as a movable device based on information obtained by the photoelectric conversion device APR.

According to the present disclosure, the yield of semiconductor devices can be improved, and the time and cost required for inspecting semiconductor devices can be reduced. Therefore, the photoelectric conversion device APR according to the present embodiment may provide a high value to a designer, a manufacturer, a seller, a purchaser, and/or a user thereof. Therefore, when the photoelectric conversion device APR is mounted on the equipment EQP, the value of the equipment EQP may also be increased. Therefore, in manufacturing and selling the equipment EQP, it is advantageous to determine the mounting of the photoelectric conversion device APR of the present embodiment on the equipment EQP in order to increase the value of the equipment EQP. Here, increasing the value corresponds to at least one of adding a function, improving performance, improving characteristics, improving reliability, improving manufacturing yield, reducing environmental load, reducing cost, reducing size, and reducing weight.

For example, by mounting the photoelectric conversion device APR in a transport device, it is possible to obtain excellent performance when photographing outside the transport device or measuring an external environment. Therefore, in manufacturing and selling the transport device, it is advantageous to determine the mounting of the photoelectric conversion device APR according to the present embodiment on the transport device in order to improve the performance of the transport device itself. In particular, the photoelectric conversion device APR is suitable for a transport device that performs driving support and/or automatic driving of the transport device using information obtained by the photoelectric conversion device APR.

### Fourth Embodiment

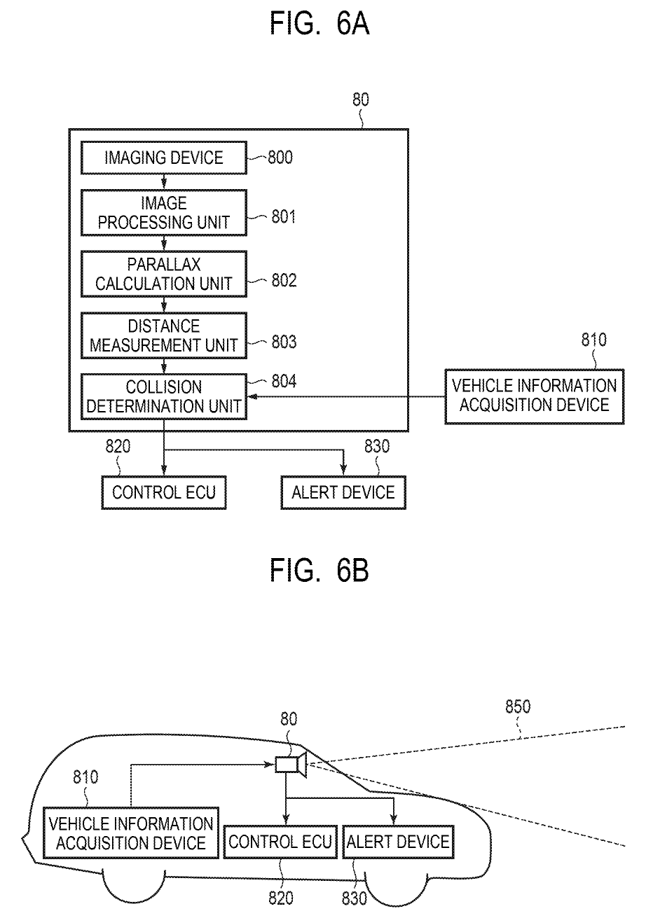

FIGS. 6A and 6B are block diagrams of equipment relating to the vehicle-mounted camera according to the present embodiment. FIGS. 6A and 6B show an example in which the above-described photoelectric conversion device is applied to a movable body such as a vehicle. The equipment 80 includes an imaging device 800 (an example of the photoelectric conversion device) and a signal processing device (processing device) that processes a signal from the imaging device 800. The equipment 80 includes an image processing unit 801 that performs image processing on multiple pieces of image data acquired by the imaging device 800, and a parallax calculation unit 802 that calculates parallax (phase difference of parallax images) from the multiple pieces of image data acquired by the equipment 80.

Here, the equipment 80 may include an optical system (not shown) that guides light to the imaging device 800. The optical system may include, for example, a lens, a shutter, and a mirror. Multiple photoelectric conversion units substantially conjugate to the pupil of the optical system may be arranged in a pixel included in the imaging device 800. For example, multiple photoelectric conversion units are arranged corresponding to one microlens. The multiple photoelectric conversion units may receive light fluxes transmitted through different positions of the pupil of the optical system. Thus, the imaging device 800 outputs multiple pieces of image data respectively corresponding to the light fluxes transmitted through different positions of the pupil of the optical system. Then, the parallax calculation unit 802 may calculate the parallax using the multiple pieces of image data being output.

The equipment 80 includes a distance measurement unit 803 that calculates a distance to an object based on the calculated parallax, and a collision determination unit 804 that determines whether or not there is a possibility of collision based on the calculated distance. Here, the parallax calculation unit 802 and the distance measurement unit 803 are examples of a distance information acquisition unit that acquires distance information to the object. That is, the distance information is information on a parallax, a defocus amount, a distance to the object, and the like. The collision determination unit 804 may determine the possibility of collision using any of these pieces of distance information. Note that the distance information may be acquired using a time of flight (ToF) technique. The distance information acquisition unit may be realized by dedicatedly designed hardware or software modules. Further, it may be realized by a field programmable gate array (FPGA), an application specific integrated circuit (ASIC) or a combination thereof.

The equipment 80 is connected to the vehicle information acquisition device 810, and can obtain vehicle information such as a vehicle speed, a yaw rate, and a steering angle. Further, the equipment 80 is connected to a control ECU 820 which is a control device that outputs a control signal for generating a braking force to the vehicle based on the determination result of the collision determination unit 804. The equipment 80 is also connected to an alert device 830 that issues an alert to the driver based on the determination result of the collision determination unit 804. For example, when the collision possibility is high as the determination result of the collision determination unit 804, the control ECU 820 performs vehicle control to avoid collision or reduce damage by braking, returning an accelerator, suppressing engine output, or the like. The alert device 830 alerts the user by sounding an alarm such as a sound, displaying alert information on a screen of a car navigation system or the like, or giving vibration to a seat belt or a steering wheel. The equipment 80 functions as a control unit that controls the operation of controlling the vehicle as described above.

In the present embodiment, an image of the periphery of the vehicle, for example, the front or the rear is captured by the equipment 80. FIG. 6B shows equipment in a case where an image is captured in front of the vehicle (image capturing range 850). The vehicle information acquisition device 810 as the imaging control unit sends an instruction to the equipment 80 or the imaging device 800 to perform the imaging operation. With such a configuration, the accuracy of distance measurement can be further improved.

Although the example of control for avoiding a collision to another vehicle has been described above, the embodiment is applicable to automatic driving control for following another vehicle, automatic driving control for not going out of a traffic lane, or the like. Furthermore, the equipment is not limited to a vehicle such as an automobile and can be applied to a movable body (movable apparatus) such as a ship, an airplane, a satellite, an industrial robot and a consumer use robot, or the like, for example. In addition, the equipment can be widely applied to equipment which utilizes object recognition or biometric authentication, such as an intelligent transportation system (ITS), a surveillance system, or the like without being limited to movable bodies.

### Modified Embodiments

The present disclosure is not limited to the above embodiments, and various modifications are possible. For example, an example in which some of the configurations of any one of the embodiments are added to other embodiments or an example in which some of the configurations of any one of the embodiments are replaced with some of the configurations of other embodiments are also embodiments of the present disclosure.

For example, an additional selector corresponding to the selectors 141 to 144 may be arranged between the redundant processor 135 and the selector 154 in the semiconductor device 11. Furthermore, an additional bypass may be arranged in the semiconductor device 11 to input the pattern signal S114.

Each functional unit included in the semiconductor device according to the present disclosure may include various circuit configurations. For example, the processors 131 to 134 and the redundant processor 135 may be signal processing circuits. Further, the scan expander 110 and the scan compressor 170 may be a signal expanding circuit and a signal compressing circuit, respectively. In addition, the selectors 121 to 123, the selectors 141 to 144, and the selectors 151 to 154 may be signal selecting circuits and may include a multiplexer.

According to the present disclosure, the yield of semiconductor devices can be improved and time and cost required for testing the semiconductor devices can be reduced.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-021191, filed February 13, 2025, which is hereby incorporated by reference herein in its entirety.

What is claimed is:

1. A method of inspecting a semiconductor device including a plurality of processors each of which has a scan chain, the method comprising:
first determining including:
inputting scan signals to the plurality of processors; and
determining whether a failure occurs in any of the plurality of processors based on output signals of the plurality of processors and an expectation value corresponding to the scan signals; and
second determining including:
inputting the scan signal to a part of the plurality of processors in a case where the first determining determines that the failure occurs; and
determining whether the failure occurs in the part of the plurality of processors based on the expectation value and an output signal of the part of the plurality of processors.

2. The method according to claim 1, wherein, in the second determining, output signals from the processors except the part of the plurality of processors are not used for determining the failure.

3. The method according to claim 2,
wherein the semiconductor device comprises a scan compressor that outputs the output signals from the plurality of processors as a single signal, and
wherein, in the second determining, the part of the plurality of processors outputs the output signal to the scan compressor, and the other processors do not output the output signals to the scan compressor.

4. The method according to claim 3, wherein, in the second determining, the scan signal is output to the scan compressor via a bypass detouring around the other processors.

5. The method according to claim 1,
wherein the part of the plurality of processors is any one processor among the plurality of processors, and
wherein the second determining includes identifying the processor having the failure by sequentially inputting the scan signal to each of the plurality of processors.

6. The method according to claim 1,
wherein the part of the plurality of processors is any one group among a plurality of groups each of which includes the processors, and
wherein the second determining includes identifying the processor having the failure by repeating:
identifying the group having the failure among the plurality of groups; and
further dividing the identified group into a plurality of groups.

7. The method according to claim 1,
wherein at least one of the plurality of processors is a redundant processor having a configuration corresponding to the processor, and
wherein, in the case where it is determined that the processor has the failure, the processor having the failure is replaced with the redundant processor.

8. The method according to claim 7 further comprising:
inputting the scan signals to the plurality of processors after replacing the processor having the failure with the redundant processor; and
determining whether the semiconductor device normally operates based on the expectation value and the output signals of the plurality of processors except the processor having the failure.

9. A semiconductor device comprising:
a plurality of processors each of which has a scan chain;
a redundant processor to be replaced with the processor having a failure, the redundant processor having a configuration corresponding to the processor;
a scan expander that expands an input signal to a plurality of scan signals;
a scan compressor that receives a plurality of output signals corresponding to the plurality of scan signals from the plurality of processors and the redundant processor, and output the plurality of output signals as a single signal;
a plurality of input signal paths that transmits the plurality of scan signals from the scan expander to the plurality of processors and the redundant processor;
a plurality of output signal paths that transmits the plurality of output signals from the plurality of processors and the redundant processor to the scan compressor; and
a plurality of bypasses used to transmit the plurality of scan signals from the scan expander to the scan compressor by detouring around the plurality of processors.

10. The semiconductor device according to claim 9 further comprising a controller that switches among the plurality of input signal paths, the plurality of output signal paths, and the plurality of bypasses,
wherein the controller executes:
a first operation including:
inputting the plurality of scan signals to the plurality of processors; and
outputting output signals corresponding to the plurality of scan signals from the plurality of processors to the scan compressor, and
a second operation including:
after executing the first operation, inputting the scan signal to a part of the plurality of processors; and
outputting an output signal corresponding to the scan signal from the part of the plurality of processors to the scan compressor.

11. The semiconductor device according to claim 10, wherein, in the second operation, the processors except the part of the plurality of processors do not output the output signals to the scan compressor.

12. The semiconductor device according to claim 11, wherein, in the second operation, a part of the plurality of scan signals is output to the scan compressor via the bypass.

13. The semiconductor device according to claim 12 further comprising a first selector arranged at the output signal path,
wherein the first selector receives:
the output signal from the processor; and
the scan signal from the scan expander via the bypass, and
wherein the controller controls the first selector to output the output signal or the scan signal to the scan compressor.

14. The semiconductor device according to claim 13 further comprising a second selector arranged at the output signal path,
wherein the second selector receives:
a selection signal from the first selector; and
the output signal from the redundant processor, and
wherein the controller controls the second selector to output the selection signal or the output signal to the scan compressor.

15. The semiconductor device according to claim 10 further comprising a third selector arranged at the input signal path,
wherein the third selector receives the scan signal from the scan expander, and
wherein the controller controls the third selector to output the scan signal to the processor or the redundant processor.

16. Equipment comprising:
a photoelectric conversion device including the semiconductor device according to claim 9; and
at least any one of:
an optical device adapted for the photoelectric conversion device,
a control device that controls the photoelectric conversion device,
a processing device that processes a signal output from the photoelectric conversion device,
a display device that displays information obtained by the photoelectric conversion device,
a storage device that stores information obtained by the photoelectric conversion device, and
a mechanical device that operates based on information obtained by the photoelectric conversion device.

17. The equipment according to claim 16, wherein the processing device acquires information on a distance from the photoelectric conversion device to an object.

18. A movable object comprising the equipment according to claim 17.
